(19) United States
(12) Patent Application Publication
(10) Pub. No.: US 2012/0312349 A1
(43) Pub. Date: Dec. 13, 2012

(54) Stationary concentrated solar power module

(76) Inventor: Arkadiy Farberov, Fremont, CA (US)

(21) Appl. No.: 13/134,476

(22) Filed: Jun. 9, 2011

(51) Int. Cl. H01L 31/052

(52) U.S. Cl. 136/246

(57) ABSTRACT

A stationary concentrated photovoltaic solar power module that is free of a tracking device and comprises a single optical lens and a plurality of photovoltaic solar cells spatially arranged on the track of a light spot produced on the photovoltaic solar cells by projection of the sun through the single optical lens unit. The cells are supported by the inner surface of the housing in the positions on the track of the light spot.

### FIELD OF THE INVENTION

The present invention relates to the field of solar power and, more specifically, to a stationary concentrated photovoltaic solar module.

### BACKGROUND OF THE INVENTION

The existing renewable energy photovoltaic devices include solar thermal devices, crystalline silicon devices, thin-film (amorphous silicon, CdTe, CIGS) devices, and concentrator devices. The latter are based on low- or high-concentration approaches. Concentrator devices, promising as they are, are still at the development stage, mostly because of their insufficient reliability for many applications. Today's concentrator photovoltaic solar (CPS) modules comprise three major components: (1) an optical concentrator (lens or mirror) that concentrates solar energy falling on the solar cell surface; (2) a solar cell (photovoltaic component) that converts light into electricity, and (3) a solar tracker (tracking unit) that is responsible for keeping the solar cells oriented toward the sun.

Concentration lenses, typically Fresnel lenses, are crucial components in today's optical concentrators of the refractive type. Compared to earlier lenses proposed by Buffon and Condorcet as a way to make large burning lenses, Fresnel lenses have a large aperture and a short focal length and are able to pass more light. They are widely used therefore in lighthouses to make the lighthouse light visible over long distances. This quality makes Fresnel lenses useful also in concentrator devices.

Fresnel lenses are usually made of transparent plastics. The choice of a particular plastic material determines the technology of making the lenses and the reliability of their operation. Fabrication technology (mostly molding) determines the geometry of the lens, its functional (optical) performance, structural (mechanical) reliability and environmental durability. Plastic Fresnel lenses have inherent shortcomings. Such lenses are comprised of numerous “microcomponents” which are combinations of randomly oriented microprisms of different geometry with different angles at their apices and at different angles with each other. The actual microprisms have rounded apices. The radii of these rounded apices (“roundings”) depend on the lens material and the fabrication technology. The smallest radii that could be achieved are about 0.1 mm. The surface of a “rounding” is an optically “dead zone”; it does not allow a light beam to pass through. For example, a circular 50-mm-diameter Fresnel lens with a plurality of 0.5-mm-spaced microprisms contains about 100 circular microprisms on its surface. This means that the “rounding” occupies about 10% of the lens' surface so that the effective optical area of this surface is reduced by about 10% compared to its geometrical area. The “rounding” results also in an additional (“parasitic”) dispersion (diffusion) of incident light.

The greatest challenge, as far as the use of Fresnel lenses in concentrator devices is concerned, stems from the fact that concentrator systems with Fresnel lenses are highly sensitive to the location of the sun with respect to the “lens-solar cell” axis. Concentrators using Fresnel lenses are able to provide a high degree of concentration, and this circumstance enables one to use small-size solar cells, thereby obtaining a rather efficient concentration device. The problem is, however, that even a small deviation in parallelism of the incident beams to the “lens-solar cell” axis considerably reduces the total energy falling on the cell surface. Appreciable deviation from parallelism leads to complete functional failure of the device. Therefore there is a need to employ a tracking unit that maintains constant orientation of the solar cells toward the sun.

It has been established that for maximal efficiency the sizes of the solar cells in the existing concentration modules are about 2 mm×2 mm (i.e., 4 mm²) and 5 mm×5 mm (i.e., 25 mm²). The smaller is the size of the solar cell and the greater is the size of the concentrator, the higher is the level of concentration. The sizes mentioned above correspond to maximum efficiency of photovoltaic devices of about 40%. The angular velocity of the rotation of the solar rays with respect to the steady-state axis of the system “concentrator lens—solar cells”, because of the Earth rotation around the sun, is 15 angular minutes per minute. With the optimal focal length of the concentration lens of about 80 mm, the illuminated spot in the focal plane is displaced during a 3-min. timeframe by an angle of 45 angular minutes. This corresponds to a linear displacement of 1 mm. This means that a 1.6×1.6 mm solar cell leaves the illuminated spot in about 3 minutes. In order to avoid this and to realize a practical concentration photovoltaic device, one must ensure continuous rotation of the device with angular velocity of 15 angular minutes per minute to follow the sun. This circumstance requires use of a highly precise, highly complex, highly sophisticated, and highly costly tracking unit. This unit is supposed to ensure that the incident concentrated sunlight is directed precisely onto the powered device in a continuous fashion. Otherwise, without a tracking unit, the concentration modules with Fresnel lenses cannot be used.

It is well known that existing tracking units, which are expensive and complex, often perform unsatisfactorily for many applications. Particularly, structural (mechanical) “inaccuracies” in design, manufacturing, and operation of these units might even exceed acceptable optical deviations and tolerances such that the performance of the concentrated photovoltaic device is functionally unsatisfactory.

A plurality of CPV systems is known in the art. Generally, such a system consists of an array of CPV modules, wherein each module typically comprises a solar energy concentrator element, e.g., a single optical lens that concentrates solar energy on a single solar cell element directly or through an auxiliary concentrator element. Some systems employ tracking units to adjust for daily and/or seasonal changes in the position of the sun.

For example, U.S. Patent Application Publication No. 20110100429 published on May 5, 2011 (inventor: H. A. Mughal) discloses a solar energy assembly that comprises a plurality of solar energy converters and an equivalent number of solar concentrator lenses, each lens being associated with one energy converter and being adapted to concentrate light onto that energy converter. The lenses may be separate from each other and may be mounted and replaced independently of the others. One or more panels may be mounted on a support frame, each panel having a plurality of solar energy converters and a lens array adapted to focus light onto the solar energy converters.

U.S. Patent Application Publication No. 20070251569 published on Nov. 1, 2007 (inventors: W. Shan, et al) discloses a fixed solar-electric module having arrays of solar concentrator assemblies capable of separately tracking movements through one or two degrees of rotational freedom to follow movement of the sun daily and/or seasonally. The concentrators can include optical elements to direct and concentrate light onto photovoltaic and/or thermoelectric receivers for generation of electrical current.

U.S. Patent Application Publication No. 20030075167 published on Apr. 24, 2003 (Inventor: M. Dominguez, et al) discloses a concentration module that consists of two optical components: concentration unit and receiver. Different possible designs of the components are addressed and discussed, and various designs of Fresnel lenses are suggested. These designs are comprised of circular Fresnel prisms of different configurations and a central free-form aspheric refractive lens. The main component of the module is a receiver, which is, in effect, also a refractive free-form aspheric lens. All components of the module are comprised of plastic and therefore possess all of the shortcomings of the plastic Fresnel lenses.

There are many other CPS systems of the above-described types, but a common disadvantage of all such systems is the relatively high cost (especially in the structures that employ moveable tracking units) and a large area occupied by the systems assembled from a plurality of CPS “one-lens/one-cell” modules.

### SUMMARY OF THE INVENTION

The present invention provides a stationary CPS solar power system that is free of a tracking device and comprises at least one CPS solar module that comprises a single optical lens unit and a plurality of photovoltaic solar cells spatially arranged on the track of a light spot produced on said photovoltaic solar cells by projection of the sun through the aforementioned single optical lens unit.

An object of the invention is to provide a design that does not need a tracking unit to constantly follow the sun but nonetheless ensures constant and highly efficient operation throughout an entire day. An additional object of the invention is to replace the Fresnel lenses with concentration lenses that would act in the same capacity as the tracking units but that would be structurally simple and that would not have mechanically moving parts. The use of freeform lenses enables one to meet these requirements. In addition, freeform lenses do not contain microprisms; their surface, although highly curvilinear, is quite smooth, and therefore no optically “dead zones’ are likely. These two major improvements in the concentration module design, namely, use of a tracking-free unit and Fresnel-lens-free photovoltaic devices, wherein each optical module consists of a single concentration lens and a plurality of cells sequentially arranged on the path of the light beam, are expected to result in significantly higher functional (optical) performance and physical (structural) reliability of the system.

In other words, the invention makes it possible to get rid of a tracking unit by making the location (placement) of the solar cells dependent on the incident angle of the incident solar rays. In the context of the invention, the incident angle is an angle of solar rays relative to the optical axis of the concentrator lens. In an immovable lens, displacement of the illuminated spot depends on the aforementioned incident angle. The illuminated spot moves along a particular trajectory. If one places the solar cells along this trajectory, then operation of the concentrator becomes possible without resorting to the need of a tracking unit. Replacement of the Fresnel lenses in light-concentration devices with free-form lenses is another important change in the existing technology. As known, a free-form optical surface is defined as a nonrotationally symmetric surface or as a symmetric surface that rotates about any axis that is not its axis of symmetry. Such free surfaces offer additional “degrees of freedom” that can be used to obtain a significantly lower wavefront error and a smaller-size device, as compared to rotationally symmetric surfaces. A free-form surface is a complex, irregular, asymmetric and aspheric surface. Free-form optics includes rotationally symmetric elements such as aspheric and parabolic. It is noteworthy that such components using free-form optical surfaces are quite common in some state-of-the-art optical instruments. Free-form lenses are effective optical concentrators that are able to ensure optimal illumination and reliable operation (functional, structural, and environmental) of a photovoltaic unit. Free-form optical surfaces embedded in a three-dimensional space, without any symmetry, could be designed (“tailored”) in such a way that they would be able to solve the original archetypal problem of an illumination design, which is to redistribute the radiation from a given light source onto a given reference surface to achieve the desired (“prescribed”) irradiance distribution on that surface. An important advantage of the free-form concept is the ability to properly co-locate the distant optical center and the near-distant optical center.

### BRIEF DESCRIPTION OF THE DRAWINGS

FIG. 1 is a simplified schematic view of the CPS module of the present invention.

FIG. 2 is a CPS solar module of FIG. 1 shown in a more specific form.

FIG. 3 is a modification of the CPS solar module with solar cells installed in a curvilinear housing.

FIG. 4 illustrates dependence of the illuminated area on the angle of incidence of the solar rays onto the concentration lens.

FIG. 5 shows “dead zones” in a package of four circular lenses.

FIG. 6 shows a package of four square lenses.

FIG. 7 is a schematic view of the CPS solar module of the invention wherein the focusing point of the lens is located between the lens and the cell.

FIG. 8 is a schematic view of the CPS solar module of the invention wherein the solar cell is located between the lens and its focusing point.

FIG. 9 shows the CPS solar module of FIG. 7 in a more specific form.

FIG. 10 is a schematic view of a CPS solar module with a free-form concentration lens.

FIG. 11 is another modification of the CPS solar module of FIG. 10.

FIG. 12 is a plan view of a solar cell having a variable width.

FIG. 13 is a plan view of a linear array of solar cells having variable lengths that increase from the center of the array toward the edges.

FIG. 14 is an example of an array of CPS modules of the invention.

### DETAILED DESCRIPTION OF THE INVENTION

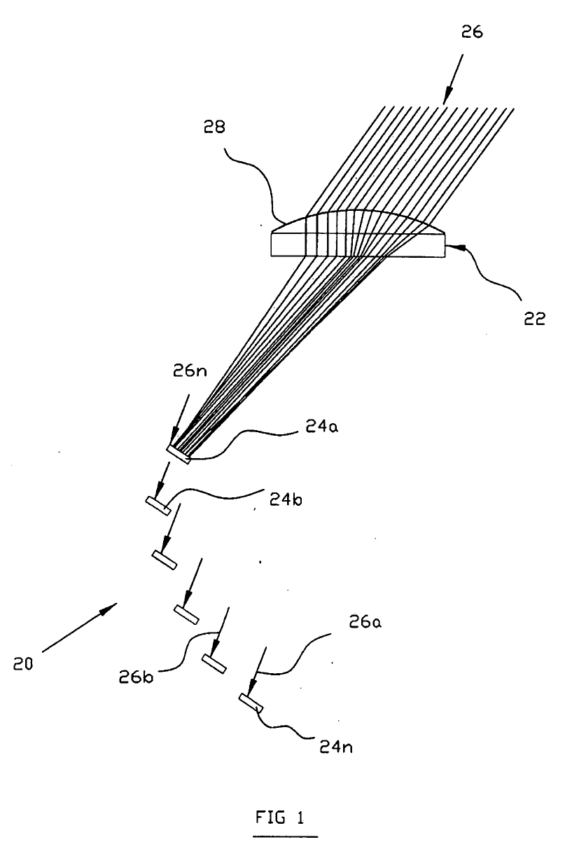

In a most simplified and generalized form, the CPS solar module of the present invention is schematically shown in FIG. 1. The module, which as a whole is designated by reference numeral 20, consists of a focusing lens 22 and a plurality of individual solar cells 24a, 24b, . . . 24n. When the lens 22 is immovable (does not change its position), the solar rays 26 fall on its receptive surface 28 at different angles, depending on the time of day and the angular velocity of the Earth around its axis. At each moment, a particular location (coordinate) of the illuminated zone depends on the geometric characteristics of the concentrated lens 22. The illuminated spots (not shown in FIG. 1), at which the solar cells 24a, 24b, . . . 24n should be placed, move along a certain trajectory, taking sequential positions 26a, 26b, . . . 26n. These positions correspond to the slope angles, e.g., of 10, 20, . . . 50 degrees, respectively.

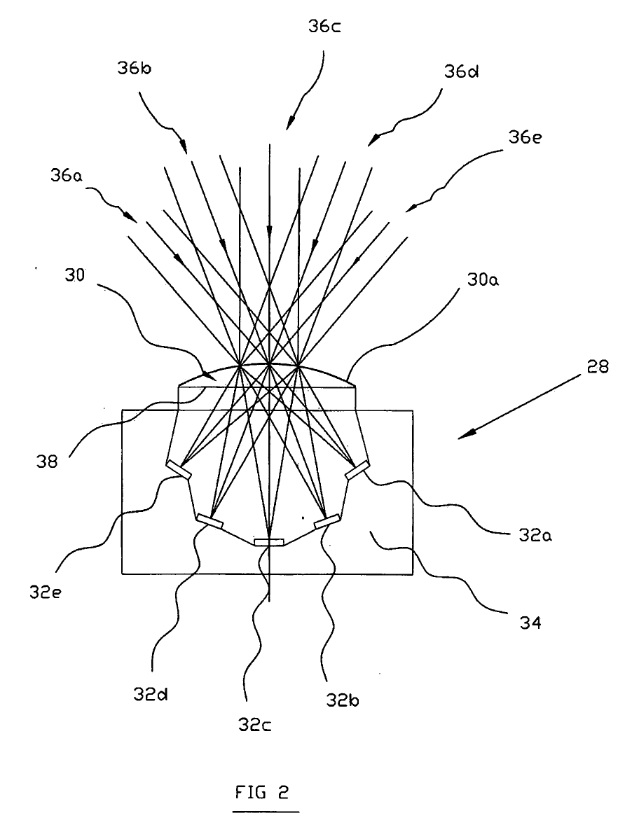

In FIG. 2 a CPS solar module 28 is shown in a more specific form that can be realized according to one or several aspects of the invention. The module 28 consists of a focusing lens 30 (that can be made of silica glass or Pyrex® or any other suitable material), a plurality of solar cells 32a, 32b, 32c, 32d, and 32e (i.e., five solar cells in the illustrated case), and a special housing 34 made, e.g., of a metal, for arrangement of the cells 32a, 32b, 32c, 32d, and 32e in positions where the cells can be exposed to the solar rays which in different positions are designated by reference numerals 36a, 36b, . . . 36n. The cells are secured inside the housing 34 in such positions that irrespective of the angle of inclination of the solar rays relative to the module, i.e., to the lens, the receiving surface of the solar cell is perpendicular to the solar rays. As the daylight commences, the solar rays 36a fall on the immovable receptive surface 30a of the concentration lens 30 at a minimal angle of the ray relative to lens 30. The light is concentrated on the solar cell 32a.

After some time, the inclination or incident angle of the solar rays changes and occupies the position shown by reference numeral 36b. In the context of the invention, the terms “inclination angle,” “incident angle,” and “angle of incidence” mean the angle of the solar rays relative to the optical axis of the concentration lens of the stationary CPS solar module. When the sun is in its zenith position, the incident ray, which is normal to the receptive surface, concentrates on the cell 32c. At the end of the solar day, the incident angle becomes small again relative to the lens, but the solar rays 36e remain perpendicular to the receiving surface of the cell 32e and are concentrated on the cell 32e. Thus, the central solar cell 32c is located on the optical axis of the concentration lens 30 in its focal plane. Any focusing lens (such as, e.g., Plano convex lens) can be used in the case in question.

The lens may have a dimension, e.g., on the order of 50 mm×50 mm, and the solar cell may have a dimension, e.g., of 2 mm×2 mm. In this case a coefficient of concentration of the solar cell is about 625. A coefficient of concentration is a ratio of the surface area of the light-receiving surface to the entire surface area of the solar cell.

The distance between the mid-plane 38 of the lens 30 and the focal plane, where the central solar cell 32c is located, is below 100 mm. In a more general situation, double convex symmetric and/or an asymmetric lenses, and/or meniscus positive lenses (spherical or aspheric) could be used as focusing lenses. When choosing and designing an optimal system, one should keep in mind that it takes 24 hours for the Earth to rotate around its axis. This means that it takes 4 min for the Earth to rotate one degree. When the distance between the lens surface and the surface of the solar cell is between 50 and 75 mm, the linear displacement of the center of the light spot on the solar cell that corresponds to one degree of the rotation of the solar rays is about 2 mm. This means that a 2×2 mm solar cell can be in the spotlight for not more than 4 minutes. To ensure continuous operation of the module when a tracker is employed, one must ensure its gradual rotation with an angular velocity of 0.3 degree per second. The smaller is the solar cell, the more accurate its rotation should be made. That is why the appropriate tracker is both complex and expensive. When the size of the solar cell increases, the requirements for precise tracking become less stringent, but concentration of the solar energy decreases as well, and so does efficiency of solar energy transformation into electrical energy. In reality, the illuminated spot has finite dimensions even at the focal point on the lens' axis and even if the solar beams fall perpendicularly to the lens surface. When the beam deviates from its normal direction, not only does the position of the light spot change, but its size and shape change as well.

FIG. 2 depicts arrangement of planar solar cells 32a, 32b, . . . 32e in the housing 34 along the route of displacement of the illuminated zone as a function of the slope angle of the solar rays falling on the lens 30. The operational conditions of photovoltaic modules depend on the daytime duration at the module location. Typically this time lasts for about 10 hours.

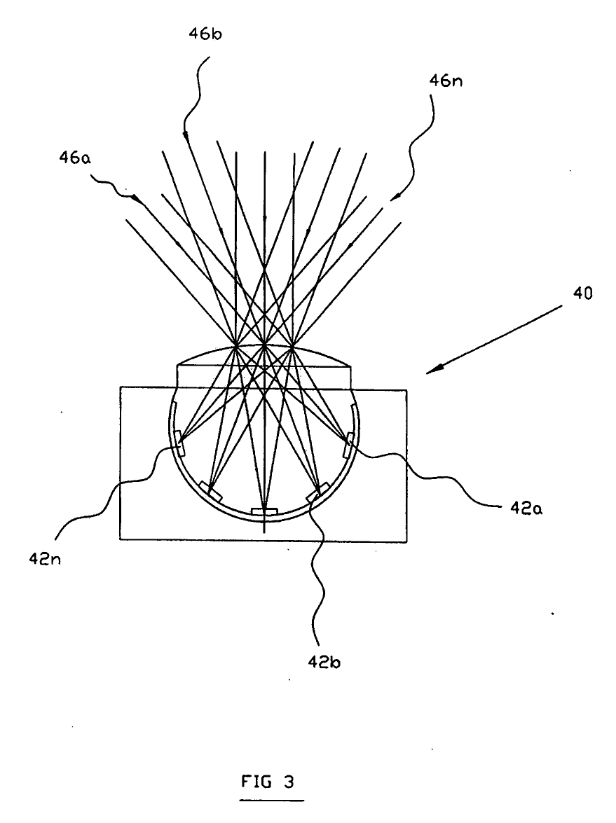

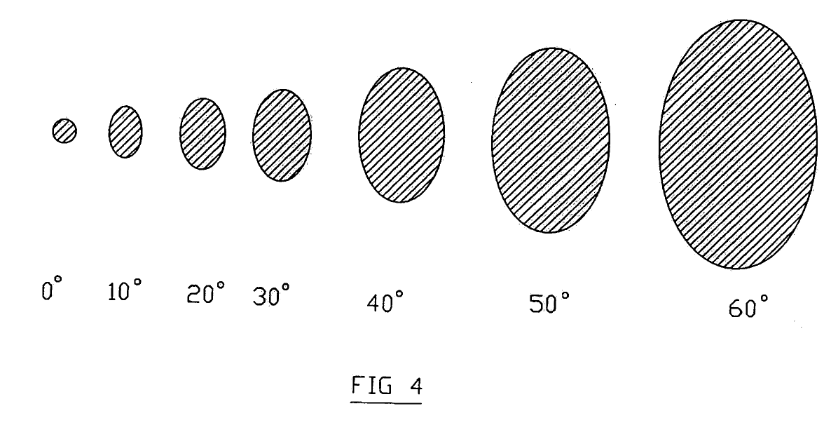

According to one or several aspects of the invention, the design of the module can be simplified. This is shown in FIG. 3, wherein a CPS solar module 40 has solar cells 42a, 42b, . . . 42n arranged on the inner side of a continuous flexible strip 44 that forms a curvilinear housing of the CPS solar module 40. The rest of the design, i.e., the lens 46, is the same as in the modification of FIG. 2. The flexible strip 44 may have a width, e.g., of 2 mm. The total area of such a flexible solar cell is also 296 mm. sq. The positions (coordinates) of the illuminated spots, i.e. of the zones where the solar cells should be placed, are also dependent on the incident angles of the solar beams 46a, 46b, . . . 46n. It is understood that the size of a photovoltaic solar cell may vary proportionally to the size of a light spot that is formed on the receiving surface of the cell. In other words, the shape and size of the illuminated zone depend substantially on the incident angle of the rays, on the location (coordinate) of the illuminated zone, and the type of concentration lens. This is shown in FIG. 4, which illustrates dependence of the illuminated angle on the angle of incidence of the solar rays onto the concentration lens, wherein the size of a photovoltaic solar cell varies proportionally to the size of said light spot.

It is clear that the size of the illuminated zone increases and the zone gets more and more spread out when the angle of incidence increases. In practice, one can easily control both the size and shape of the illuminated zone by changing the angle of inclination of the solar cell at a particular location of the light spot on the curvilinear trajectory of its movement.

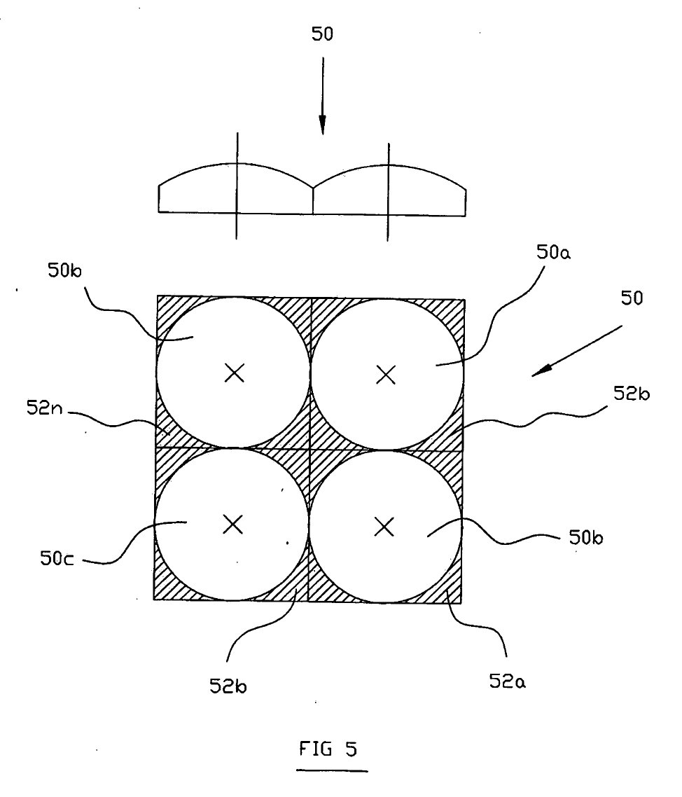

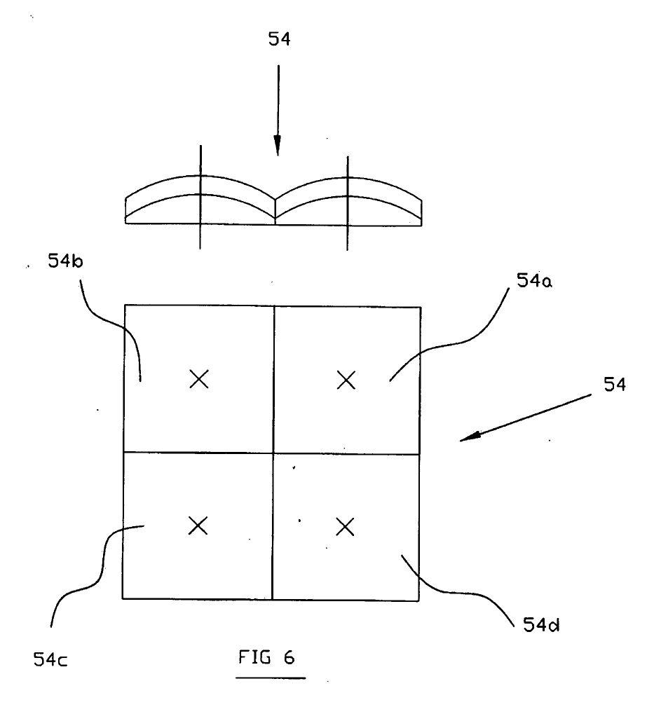

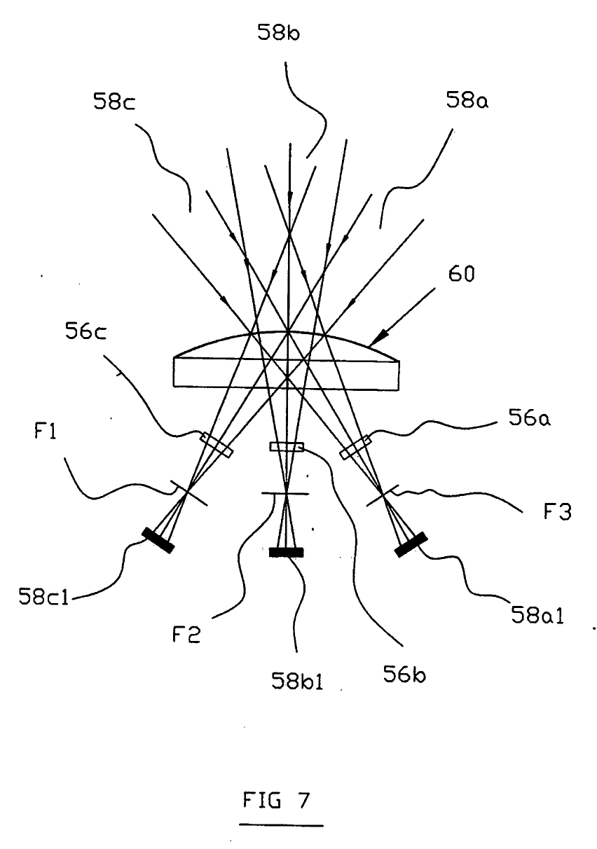

When, as shown in FIG. 5, circular lenses, e.g., lenses 50a, 50b, 50c, and 50d, are assembled into a panel 50, a large portion of the surface of the completed module remains idle because of the “dead” spots 52a, 52b, . . . 52n (hatched areas between the lenses in FIG. 5). As shown in FIG. 6, this problem can be easily resolved when the panel 54 is formed of square lenses, e.g., such as 54a, 54b, 54c, and 54e. According to one or several aspects of the invention, solar cells 56a, 56b, and 56c can be placed on the path of the solar rays 58a, 58b, and 58c between the sequential positions F1, F2. and F3 of the focal plane of the common lens 60 and the lens itself, or they can be placed behind the focal plane F1, F2, and F3e solar cell images 56a1, 56b1, and 56c1, as shown in FIG. 7.

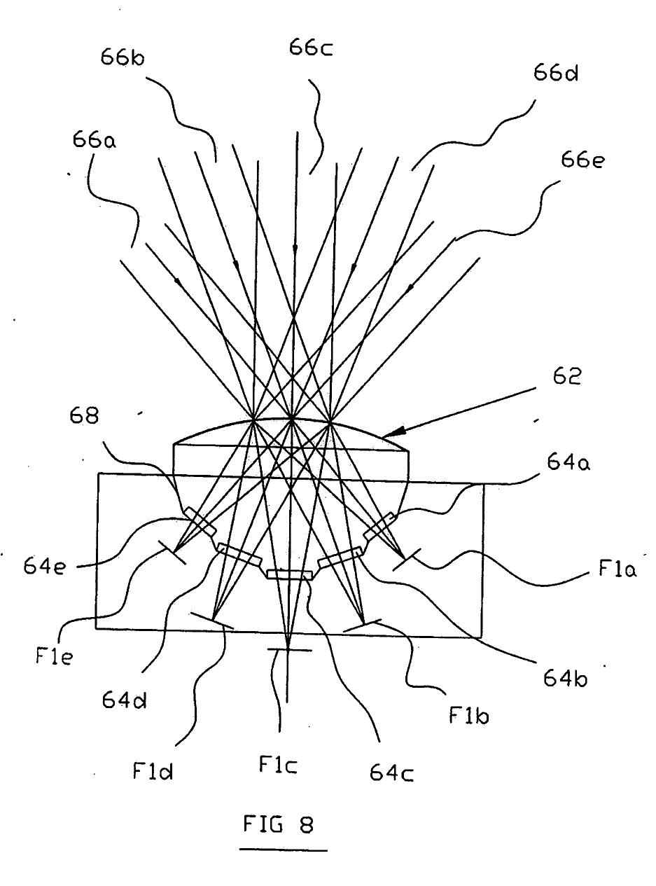

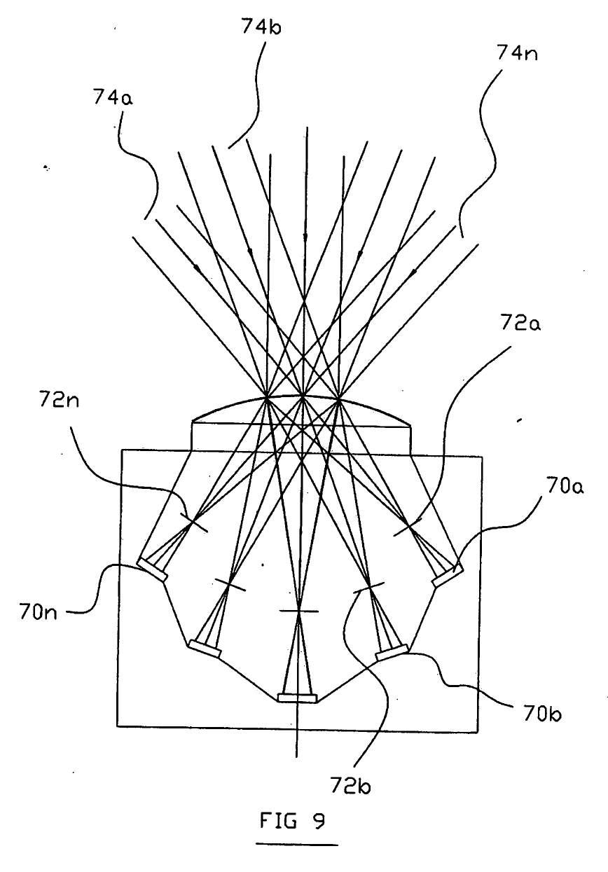

In order to provide more uniform illumination of the cells, they should be placed in the zone between the focal plane and the lens. This is shown in FIG. 8 which depicts a five-cell module, wherein reference numeral 62 designates a concentration lens, 64a, 64b, 64c, 64d, and 64e designate solar cells, and F1a, F2b, F2c, F2d, and F2e designate sequential positions of the focal plane. The coordinates of the illuminated cells depend in this case on the slope angle of the sequential positions of the incident rays, the positions of which are designated by reference numerals 66a, 66b, 66c, 66d, and 66e, respectively. Reduction in the concentration of radiation and, as a result, reduction in the temperature at the focal point of illumination can be easily achieved by defocusing the system when solar cells are placed between the lens and its moving focal plane. In this case, a light spot will have a circular shape while the solar cells may have a square configuration. In FIG. 9 it is shown that the same effect can be achieved if the solar cells 70a, 70b, . . . 70n are placed behind the focal plane 72. Illumination of the solar cells in this case is analogous to the situation wherein the cells are located in front of the focal plane but the trajectory of the arrangement of the illuminated zones becomes simpler and depends on the incident angle of the solar rays shown in sequential positions by reference numerals 74a, 74b, . . . 74n. For critical angles of inclination of the solar beams, the illuminated zone could turn out to be on the rear surface of the lens, which could make the arrangement of the solar cells more difficult. In such a situation, one could locate the solar cells in the diverging/radiation zone after the beams leave the focal plane, as shown in FIG. 9. One could also simplify the curvilinear surface of the housing 3 and adjust (optimize) the shape of the light spot.

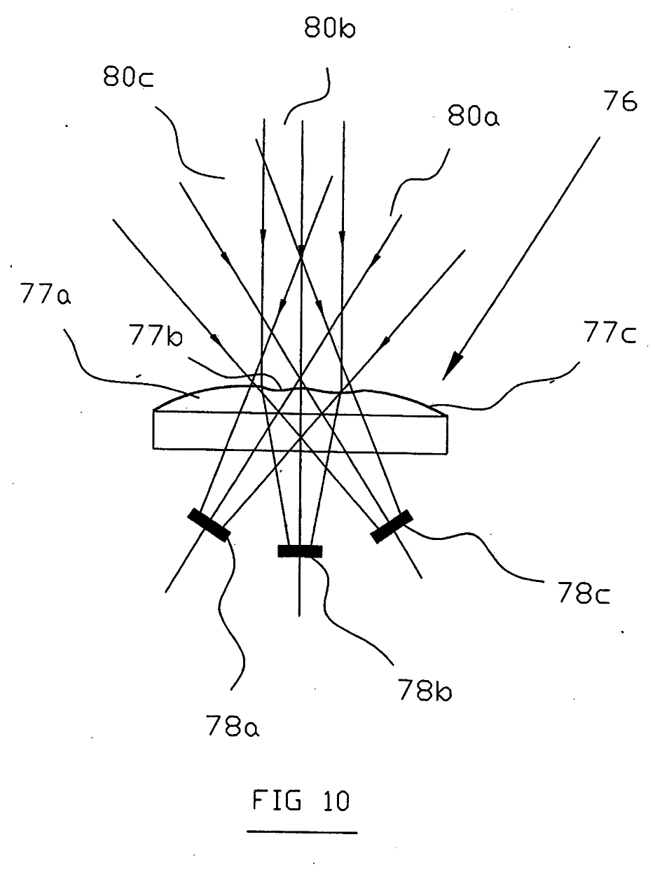

According to one or several aspects of the invention, more uniform illumination of the solar cells can be achieved by employing a free-form concentration lens. This is shown in FIG. 10 which shows a free-form concentration lens 76 that consists of three profiled portions 77a, 77b, and 77c shaped so that the solar cells 78a, 78b, and 78c receive the solar beams (which at different incident angles are designated by reference numerals 80a, 80b, and 80c) perpendicular to the flat light-receiving planes of the respective cells 78a, 78b, and 78c. Although the module is shown with three solar cells, this is only an example, and the single free-form lens 76 of this modification may have a free profile with a plurality of profiled portions and a respective plurality of solar cells.

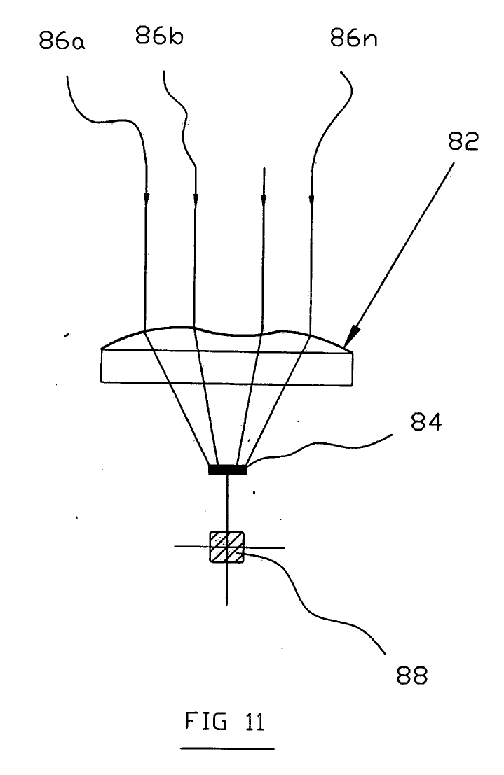

FIG. 11 shows that the use of a free-form concentration lens 82 makes it possible to obtain on a solar cell 84 a light spot of a given shape with maximized and uniform illumination of the cell “working zone.” This is achieved by using the free-form lens 84 with focusing of lightbeams 86a, 86b, . . . 86n into a square 88 of a given size. The structure of the free-form lenses enables one to focus and to collect all of the solar energy that falls on the receptive surface of the cell in a given zone and to uniformly distribute it over this zone.

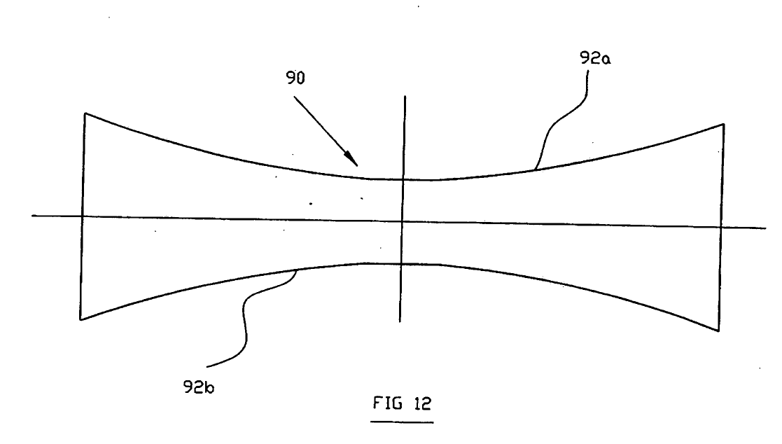

FIG. 12 shows a CPS solar module according to one or several aspects of the invention. In this case a solar cell, e.g., such as solar cell 90, can be made from a flexible optical material, e.g., thin film, single crystal silicon, amorphous silicon, or the like, and may have a variable width. For example, the solar cell 90 may have both side surfaces curved along curvilinear profiles 92a and 92b with gradual thinning of cell width from the peripheral edges toward the center. Use of such solar cells makes it possible to ensure continuous operation of the module and more efficient use of the illuminated zone.

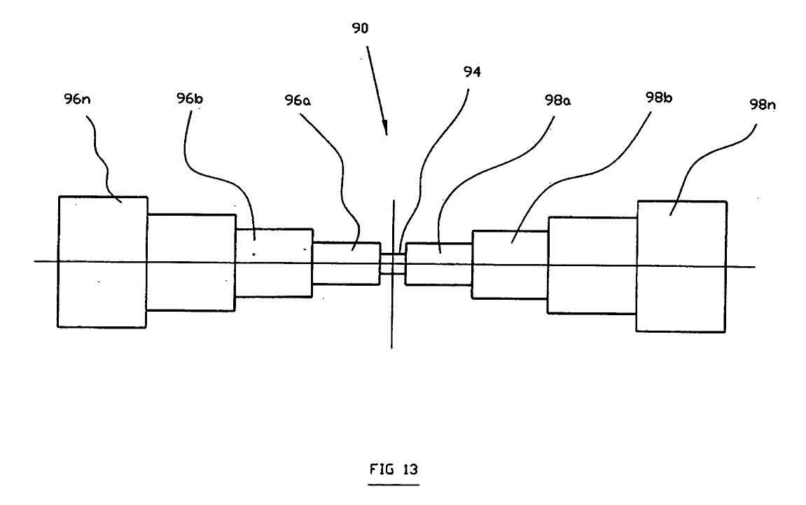

A similar effect could be achieved with solid solar cells, as shown in FIG. 13, which is a plan view of the linear array of the cell. In this modification, the solar cells 94, 96a, 96b, . . . 98a, 98b, . . . 98n are arranged in line, and their width is increased from the center (cell 94) toward the edges (96a->96b-> . . . 96n, etc.) in a stepped manner. The width of the solar cells depends in this case on their location (coordinate) on the trajectory of the illuminated spot (zone). In other words, the width of the solar cell is changed in order to accommodate the size of the illuminated zone.

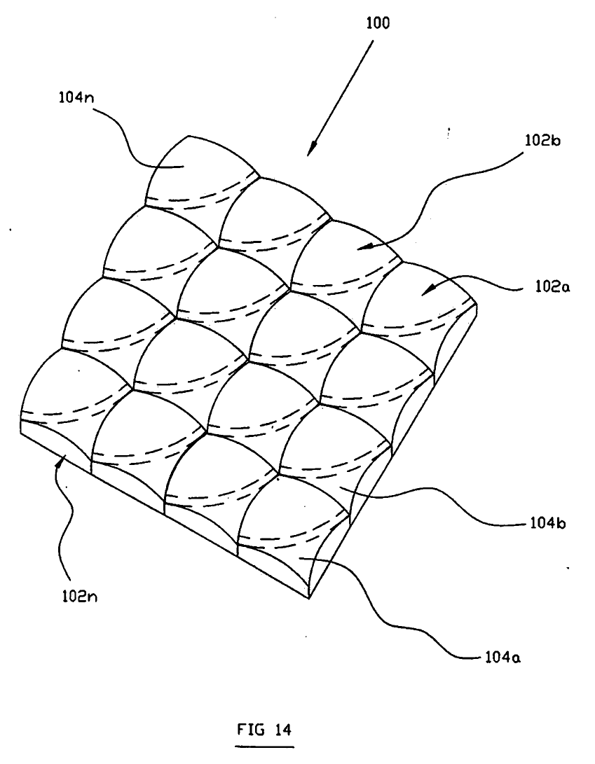

It is understood that a plurality of CPS solar modules of the types shown in FIGS. 2 to 10 can be assembled into arrays of the type shown in FIG. 14. The two-dimensional CPS solar module array 100 is composed of a plurality of linear CPS solar module arrays 102a, 102b, . . . 102n arranged side by side, wherein each individual module 104a, 104b, . . . 104n comprises a single concentration lens and a plurality of individual solar cells located within the area that can be illuminated by solar rays.

Although the invention has been shown and described with reference to specific embodiments, it is understood that these embodiments should not be construed as limiting the areas of application of the invention and that any changes and modifications are possible, provided that these changes and modifications do not depart from the scope of the attached patent claims. For example, the concentration lenses may have different shapes and dimensions provided that they ensure illumination of the plurality of solar cells located in the module. The solar cells may have different shapes and dimensions as well. The modules may be organized into arrays of different shapes and configurations. The solar cells in the arrays can be oriented in the diagonal direction of the square lenses located on the concentration panel.

1. A stationary concentrated photovoltaic solar power module, which is free of a tracking device and comprises a single optical lens and a plurality of photovoltaic solar cells spatially arranged on the track of a light spot produced on said photovoltaic solar cells by projection of the sun through said single optical lens unit; each photovoltaic solar cell of said plurality having a receiving surface onto which the solar ray falls.

2. The stationary concentrated photovoltaic solar power module of claim 1, further comprising a housing having an inner surface, the photovoltaic solar cells being supported by the inner surface of the housing in the positions on the track of the light spot.

3. The stationary concentrated photovoltaic solar power module of claim 2, wherein the photovoltaic solar cells are secured in the housing in such positions, in which irrespective of the angle of inclination of the solar ray relative to the single optical lens, the receiving surface of the solar cell is perpendicular to the solar ray.

4. The stationary concentrated photovoltaic solar power module of claim 3, wherein the photovoltaic solar cells are installed on a continuous flexible strip is formed into the housing that has a curvilinear shape.

5. The stationary concentrated photovoltaic solar power module of claim 1, wherein the size of the photovoltaic solar cell varies proportionally to the size of said light spot.

6. The stationary concentrated photovoltaic solar power module of claim 2, wherein the size of the photovoltaic solar cell varies proportionally to the size of said light spot.

7. The stationary concentrated photovoltaic solar power module of claim 3, wherein the size of the photovoltaic solar cell varies proportionally to the size of said light spot.

8. The stationary concentrated photovoltaic solar power module of claim 4, wherein the size of the photovoltaic solar cell varies proportionally to the size of said light spot.

9. The stationary concentrated photovoltaic solar power module of claim 1, wherein said single optical lens has a focusing point and wherein each photovoltaic solar cell is located in a position at which the focusing point is located behind the solar cell.

10. The stationary concentrated photovoltaic solar power module of claim 1, wherein said single optical lens has a focusing point and wherein each photovoltaic solar cell is located in a position at which the focusing point is located between the single optical lens and the photovoltaic solar cell.

11. The stationary concentrated photovoltaic solar power module of claim 3, wherein said single optical lens has a focusing point and wherein each photovoltaic solar cell is located in a position at which the focusing point is located behind the solar cell.

12. The stationary concentrated photovoltaic solar power module of claim 3, wherein said single optical lens has a focusing point and wherein each photovoltaic solar cell is located in a position at which the focusing point is located between the single optical lens and the photovoltaic solar cell.

13. The stationary concentrated photovoltaic solar power module of claim 1, wherein the single optical lens is a free-form lens that consists of a plurality of profiled portions shaped so that the photovoltaic solar cells receive the solar ray perpendicular to their receiving surfaces.

14. The stationary concentrated photovoltaic solar power module of claim 2, wherein the single optical lens is a free-form lens that consists of a plurality of profiled portions shaped so that the photovoltaic solar cells receive the solar ray perpendicular to their receiving surfaces.

15. The stationary concentrated photovoltaic solar power module of claim 3, wherein the single optical lens is a free-form lens that consists of a plurality of profiled portions shaped so that the photovoltaic solar cells receive the solar ray perpendicular to their receiving surfaces.

16. The stationary concentrated photovoltaic solar power module of claim 11, wherein the single optical lens is a free-form lens that consists of a plurality of profiled portions shaped so that the photovoltaic solar cells receive the solar ray perpendicular to their receiving surfaces.

17. The stationary concentrated photovoltaic solar power module of claim 12, wherein the single optical lens is a free-form lens that consists of a plurality of profiled portions shaped so that the photovoltaic solar cells receive the solar ray perpendicular to their receiving surfaces.

18. The stationary concentrated photovoltaic solar power module of claim 3, wherein each photovoltaic solar cell is made from a flexible optical material and has a variable width that increases from the center to the edges of the photovoltaic solar cell.

19. The stationary concentrated photovoltaic solar power module of claim 18, wherein the width of the photovoltaic solar cell changes from the center to the edges of the photovoltaic solar cell continuously.

20. The stationary concentrated photovoltaic solar power module of claim 18, wherein the width of the photovoltaic solar cell changes from the center to the edges of the photovoltaic solar cell in a stepped manner.
